(19) United States
(12) Patent Application Publication
(10) Pub. No.: US 2024/0175132 A1
(43) Pub. Date: May 30, 2024

(54) MULTI-DISC CHEMICAL VAPOR DEPOSITION SYSTEM

(71) Applicant: VEECO INSTRUMENTS INC., Plainview, NY (US)

(72) Inventors: Ajit Paranjpe, Plainview, NY (US); Alexander Gurary, Plainview, NY (US); Bojan Mitrovic, Friedberg (DE)

(73) Assignee: VEECO INSTRUMENTS INC., Plainview, NY (US)

(21) Appl. No.: 18/519,476

(22) Filed: Nov. 27, 2023

Related U.S. Application Data
(60) Provisional application No. 63/428,261, filed on Nov. 28, 2022.
(60) Provisional application No. 63/428,250, filed on Nov. 28, 2022.

(51) Int. Cl. C23C 16/458; C23C 16/448; C23C 16/455

(52) U.S. Cl. CPC C23C 16/4584; C23C 16/4481; C23C 16/455

(57) ABSTRACT

A multi-wafer metal organic chemical vapor deposition system in which adjacent wafers positioned within the system rotate about their own axes, including a reaction chamber comprising an exhaust system including a peripheral port, a multi-wafer carrier comprising a wafer carrier body and a plurality of wafer carrier discs supported within the wafer carrier body, wherein adjacent wafer carrier discs of the plurality wafer carrier discs are configured and the wafer carrier body are configured to rotate at different speeds, a multi-zone injection block positioned over the wafer carrier body, a central gas port positioned in the center of the wafer carrier body functions as a gas exhaust, and a multi-zone heater assembly positioned beneath the multi-wafer carrier.

### CROSS REFERENCE TO RELATED APPLICATION

The present application claims the benefit of and priority to U.S. patent application Ser. No. 63/428,261, filed Nov. 28, 2022, and U.S. patent application Ser. No. 63/428,250, filed Nov. 28, 2022, each of which is hereby incorporated by reference in its entirety.

### TECHNICAL FIELD

The present technology is generally related to semiconductor fabrication technology and, more particularly to chemical vapor deposition processing and associated systems having the high-performance standards of a single wafer reactor, with the productivity metrics of a high-capacity, multi-wafer batch reactor.

### BACKGROUND

Certain processes for fabrication of semiconductors can require a complex process for growing epitaxial layers to create multilayer semiconductor structures for use in fabrication of high-performance devices, such as light emitting diodes (LEDs), laser diodes, optical detectors, power electronics, and field effect transistors. In this process, the epitaxial layers are grown through a general process called chemical vapor deposition (CVD). One type of CVD process is called metal organic chemical vapor deposition (MOCVD). In MOCVD, reactant gases are introduced into a reactor chamber within a controlled environment that enables the reactant gas to react on a substrate (commonly referred to as a “wafer”) to grow thin epitaxial layers.

During epitaxial layer growth, several process parameters are controlled, such as temperature, pressure, and gas flow rate, to achieve desired quality in the epitaxial layers. Different layers are grown using different materials and process parameters. For example, devices formed from compound semiconductors such as III-V semiconductors, typically are formed by growing a series of distinct layers. In this process, the wafers are exposed to a combination of reactant gases, typically including a metal organic compound such as an alkyl source that includes a group III metal, such as aluminum (Al), gallium (Ga), indium (In), and combinations thereof, and a hydride source that includes a Group V element, such as nitrogen (N), phosphorus (P), arsenic (As), or antimony (Sb), typically in the form of NH₃, AsH₃, PH₃, or an Sb metalorganic, such as tetramethyl antimony. Generally, the alkyl and hydride sources are combined with a carrier gas, such as nitrogen (N₂), hydrogen (H₂), or a mixture of both which do not participate appreciably in the reaction. In these processes, the alkyl and hydride sources flow over the surface of the wafer and react with one another to form a III-V compound of the general formula IN_{X}GA_{Y}Al_{Z}N_{A}A_{SB}P_{C}Sb_{D}, where X+Y+Z equals approximately one, A+B+C+D equals approximately one, and each of X, Y, Z, A, B, C, and D can be between zero and one. In other processes, commonly referred to as “halide” or “chloride” processes, the Group III metal source is a volatile halide of the metal or metals, most commonly a chloride such as GaCl₂. In yet other processes, bismuth is used in place of some or all the other Group III metals.

A suitable substrate for the reaction can be in the form of a wafer having metallic, semiconducting, and/or insulating properties. In some processes the wafer can be formed of sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

In a rotating disk reactor architecture-based CVD process chamber, one or more wafers are positioned within a rapidly-rotating carousel, commonly referred to as a “wafer carrier,” so that the top surface of each wafer is exposed, thereby providing a uniform exposure of the top surface of the wafer to the atmosphere within the reactor chamber for the deposition of semiconductor materials. The wafer carriers are typically machined out of a highly thermally conductive material such as graphite and are often coated with a protective layer of a material such as silicon carbide or tantalum carbide. Each wafer carrier has a set of circular indentations, or pockets, in its top surface in which individual wafers are placed. The wafer carrier is commonly rotated at a rotation speed on the order from about 50 to 1500 RPM or higher. While the wafer carrier is rotated, the reactant gases are introduced into the chamber from a gas distribution device, positioned upstream of the wafer carrier. The flowing gases pass downstream toward the wafer carrier and wafers, desirably in a laminar flow.

During the CVD process, the wafer carrier is maintained at a desired elevated temperature by heating elements, often positioned beneath the wafer carrier. Therefore, heat is transferred from the heating elements to the bottom surface of the wafer carrier and flows upwardly through the wafer carrier to the one or more wafers. Depending on the process, the temperature of the wafer carrier is maintained on the order of between about 550-1200° C. for GaN based films. Higher temperatures (e.g., up to about 1450° C.) are used for growth of AlN based films and lower temperatures (e.g., down to about 350° C.) are used for growth of AsP films. Other temperature ranges are suitable for other materials such as SiC, Si and SiGe or 2D materials such as graphene, and sulphides or selenides of tungsten and molybdenum. The reactant gases, however, are introduced into the chamber by the gas distribution device at a much lower temperature, typically about 200° C., or lower (50° C.-80° C.), to inhibit premature reaction of the gases.

As the reactant gases approach the rotating wafer carrier, the temperature of the reactant gases substantially increases and viscous drag of the rotating wafer carrier impels the gases into rotation about an axis of the wafer carrier, so that the gases flow around the axis and outwardly toward a perimeter of the wafer carrier across the boundary region near the surface of the wafer carrier. Depending on the reactant gases used in the process, pyrolysis can occur in or near the boundary region at an intermediate temperature between that of the gas distribution device and the wafer carrier. This pyrolysis creates intermediate species that facilitate growth of a crystalline structure. The gases that are not consumed continue to flow toward the perimeter and over the outer edge of the carrier, where they are removed from the process chamber through one or more exhaust ports disposed below the wafer carrier.

Presently, two broad categories of process chambers exist today that are based on the rotating disk reactor concept: (1) high-performance single wafer reactors, such as the PROPEL™ GaN MOCVD system, manufactured by Veeco Instruments Inc. of Plainview, NY, capable of depositing high-quality GaN films on 200 mm (8 inch) silicon wafers for applications such as power, RF and photonics; and (2) high-capacity multi-wafer reactors, such as the TurboDisc EPIK® family of MOCVD systems, also manufactured by Veeco Instruments Inc. of Plainview, NY, designed for mass production of mini- and micro-LEDs, typically on 100 mm (4 inch) or 150 mm (6 inch) silicon wafers, and a related family of products referred to as K475i and Lumina for growth of AsP based films. Although such systems have proven to work exceptionally well, there is a continuing desire to produce even higher efficiency process chambers, which have a higher capex efficiency (ratio of throughput to capital investment), smaller footprints and lower associated operating costs, while maintaining the high-quality deposition standards required, for example, of certain GaN film applications.

In particular, several emerging applications (e.g., micro-LEDs) place very stringent requirements on the uniformity of the wavelength and film thickness while also requiring very low defectivity levels to be achieved. For blue micro-LEDs for example, the range of acceptable wavelengths is 2 nm, the range of thickness variation is 4%, and the allowable defectivity levels for defects larger than 1 μm is 0.1/cm². To achieve these stringent requirements, uniformity must be achieved simultaneously for several parameters over the substrate. This includes the gas flow rate, boundary layer thickness, gas temperature, and wafer temperature. Since the substrate bows appreciably during the growth and its bow differs during various stages of growth, dynamic temperature control of the pocket under the wafer is necessary to ensure that a uniform wafer temperature is maintained during all stages of growth. A single wafer reactor in which the substrate is spinning about its axis and the gas flow towards the substrate encounters the wafer before flowing over the carrier provides these attributes, while to date these same attributes have been impossible to consistently achieve in a conventional multi-disc batch reactor. The present disclosure addresses this concern.

### SUMMARY OF THE DISCLOSURE

The techniques of this disclosure generally relate to chemical vapor deposition processing systems and associated methods having the high-performance deposition standards of a single wafer reactor, with the productivity metrics of a high-capacity, multi-wafer batch reactor. In embodiments, the present disclosure includes reactors capable of processing multiple high-speed rotating disks, with each disk emulating a single wafer reactor integrated into a batch reactor, so that a common gas delivery system, injector, heater assembly, in-situ metrology, chamber body, exhaust, and rotation mechanism can be shared between the discs. To achieve a high degree of consistency in epitaxial growth, in some embodiments, for example, the discs can be rotated in a circular, oval, racetrack or any other closed path within the chamber, such that each of the discs experience a nearly identical time averaged process environment. Accordingly, embodiments of the present disclosure describe higher capex efficiency, more compact (e.g., smaller footprint) chemical vapor deposition systems with lower operating costs, without compromising deposition quality.

One embodiment of the present disclosure provides a multi-wafer metal organic chemical vapor deposition system in which adjacent wafers positioned within the system rotate about their own axes, including a reaction chamber having an exhaust system, a multi-wafer carrier including a wafer carrier body and a plurality of wafer carrier discs supported within the wafer carrier body, and an injection block having at least one injection zone positioned over the multi-wafer carrier

Another embodiment of the present disclosure provides a multi-wafer carrier for a chemical vapor deposition configured to minimize growth rate non-uniformity induced around an edge of substrate wafers positioned within the multi-wafer carrier during a chemical vapor deposition process, including a wafer carrier body, a plurality of wafer carrier discs supported within the wafer carrier body, and a cover plate configured to transition relative to an upper surface of the wafer carrier body between a home position and an active position.

In one embodiment, the cover plate is transitioned between the home position and the active position by a lift mechanism comprising an actuator. In one embodiment, the wafer carrier body and the cover plate rotate together. In one embodiment, the reactor further includes a drive mechanism to move the cover plate between the home position and the active position. In one embodiment, the cover plate is water-cooled. In one embodiment, the cover plate defines a plurality of openings corresponding to each of the substrate wafers positioned within the multi-wafer carrier. In one embodiment, the openings at least partially overlap portions of the substrate wafers positioned within the multi-wafer carrier. In one embodiment, the openings are at least one of circular, oval, or non-polygonal shape configured to optimize deposition uniformity. In one embodiment, the cover plate is constructed of at least a semi-transparent material.

The drive mechanism can comprise a lift mechanism for moving the cover plate between the lowered home position and the raised operating position and the lift mechanism is configured to permit rotation of the multi-wafer carrier. The lift mechanism can, in one embodiment, include a plurality of lift pins that pass through corresponding through holes in the multi-wafer carrier and are configured to drive the cover plate from the lowered home position to the raised operating position and permit lowering of the cover plate. The lift mechanism is rotatable to accommodate rotation of the wafer carrier. In addition, the lift mechanism includes a motor that is configured to controllably rotate the cover plate between a plurality of indexed positions. When the reaction chamber includes a center exhaust port, the lift mechanism can be at least partially located in the center exhaust port that is located in a center of the multi-wafer carrier.

Another embodiment of the present disclosure provides a precision, multi-wafer metal organic chemical vapor deposition system, including a reaction chamber, a multi-zone injector, a multi-wafer carrier having a wafer carrier body and a plurality of wafer carrier discs supported within the wafer carrier body, and a cover plate configured to be raised and lowered relative to an upper surface of the multi-wafer carrier.

In one embodiment, the cover plate is water-cooled. In one embodiment, the cover plate defines a plurality of openings corresponding to the plurality of wafer carrier discs.

Another embodiment of the present disclosure provides a multi-wafer metal organic chemical vapor deposition system in which adjacent wafers positioned within the system spin about their own axis. The system includes a reaction chamber comprising an exhaust system including a central port and a peripheral port, a multi-zone injection block comprising at least a first alkyl zone, a second alkyl zone, at least one hydride zone, and one or more purge zones, a multi-wafer carrier comprising a wafer carrier body and a plurality of wafer carrier discs supported within the wafer carrier body, wherein adjacent wafer carrier discs of the plurality of wafer carrier discs are configured to rotate either in the same direction or in opposite directions to one another, and a multi-zone heater assembly positioned beneath the multi-wafer carrier.

In one embodiment, the multi-zone injector block, which typically includes an array of ports, can define one or more linear or arcuate (i.e., annular) ports to introduce reactant gases into the reaction chamber. In one embodiment, the multi-zone heater assembly comprises at least an individually controllable first zone, a second zone and a third zone. Additional zones such as a fourth zone may be included for improved temperature uniformity and controllability. In one embodiment, the first zone, second zone and third zone are arranged beneath the multi-wafer carrier to enable regulation of a radial heat profile of each of the plurality of wafer carrier discs. In one embodiment, the wafer carrier body is configured to rotate relative to the reaction chamber at a rate of between about 10 RPM and about 30 RPM. In one embodiment, each of the plurality of wafer supporting discs mounted within the wafer carrier body are configured to rotate relative to the reaction chamber at a rate of between about 600 RPM and about 1200 RPM. Even higher rotational speeds (up to about 3000 rpm) may be achieved for certain applications. In one embodiment, the multi wafer carrier body is supported and driven by a platform ring, while a satellite ring drives the plurality of wafer carrier discs (also referred to as satellite discs or satellites).

Another embodiment of the present disclosure provides a multi-wafer carrier for a chemical vapor deposition system, including a platform ring rotatably coupled to a base, the platform ring comprising a plurality of wafer carrier supports configured to support a wafer carrier body, and a plurality of satellite supports configured to support a corresponding plurality of individual satellites mounted within the wafer carrier body, wherein the plurality of satellites supports are configured to rotate relative to the platform ring, with adjacent satellite supports rotating in the same or opposite directions to one another.

In one embodiment, the wafer carrier body is configured to rotate relative to the base at a rate of between about 10 RPM and about 30 RPM. In one embodiment, the individual satellites mounted within the wafer carrier body are configured to rotate relative to the base at a rate of between about 600 RPM and about 1200 RPM. In one embodiment, the wafer carrier further includes a satellite ring rotatably coupled to the platform ring, the satellite ring configured to drive a rotation of the plurality of satellites. In one embodiment, the satellite ring defines a plurality of gear teeth configured to mesh with gears associated with the plurality of individual satellite supports. In one embodiment, half of the satellite supports further comprise a reversal gear configured to reverse a rotational direction of half of the wafer carrier discs supports.

Another embodiment of the present disclosure provides a precision, multi-wafer metal organic chemical vapor deposition system, including a reaction chamber comprising including a central exhaust port, one or more peripheral exhaust ports, a multi-zone injection block including a centrally located inner purge at least partially surrounded by an outer purge, a multi-wafer carrier comprising a wafer carrier body and a plurality of satellites supported within the wafer carrier body, and a heater assembly positioned beneath the multi-wafer carrier. The conductance of the exhaust ports is controlled by the throttle valve in line with the exhaust port, while the chamber pressure is controlled by a throttle valve positioned in the foreline to the pump inlet. In this manner, the gas flow can be controllably distributed through the center exhaust port and peripheral exhaust port while the chamber pressure can be independently controlled.

The summary above is not intended to describe each illustrated embodiment or every implementation of the present disclosure. The figures and the detailed description that follow more particularly exemplify these embodiments.

### BRIEF DESCRIPTION OF THE DRAWINGS

The disclosure can be more completely understood in consideration of the following detailed description of various embodiments of the disclosure, in connection with the accompanying drawings, in which:

FIG. 1 is an exploded perspective view depicting a precision, multi-wafer metal organic chemical vapor deposition system configured to achieve the performance of a single wafer reactor, with the productivity and efficiency of a multi-disc batch reactor, is depicted in accordance with an embodiment of the disclosure.

FIG. 2 is a cross-sectional view depicting a precision, multi-wafer metal organic chemical vapor deposition system configured to achieve the performance of a single wafer reactor, with the productivity and efficiency of a multi-disc batch reactor, is depicted in accordance with an embodiment of the disclosure. Optionally included is a movable cover plate with associated lift and rotational mechanism.

FIG. 3 is a perspective view depicting a planetary wafer carrier drive mechanism configured to rotate at least two individual wafer supporting discs in counter-rotating pairs, while at the same time rotating wafer carrier itself in either of a clockwise or counterclockwise direction, in accordance with an embodiment of the disclosure.

FIG. 4 is a partial, cross-sectional view depicting a precision, multi-wafer metal organic chemical vapor deposition system configured to achieve the performance of a single wafer reactor, with the productivity and efficiency of a multi-disc batch reactor, in accordance with an embodiment of the disclosure.

FIG. 5 is a cross-sectional schematic view depicting a multi-zone injector including at least two distinct zones for the distribution of reactant gases into a reaction chamber, in accordance with an embodiment of the disclosure.

FIG. 6A is a plan view a multi-zone injector including linear ports defining at least two distinct zones for the distribution of reactant gases into a reaction chamber, in accordance with an embodiment of the disclosure.

FIG. 6B is a plan view a multi-zone injector including arcuate or oval ports defining at least two distinct zones for the distribution of reactant gases into a reaction chamber, in accordance with an embodiment of the disclosure.

FIG. 7 is a partial, cross-sectional view depicting a precision, multi-wafer metal organic chemical vapor deposition system including a multi-zone heater assembly and multi-port exhaust system, in accordance with an embodiment of the disclosure.

FIG. 8 is a graphic depiction of a wafer carrier pocket temperature across a radius of a wafer positioned therein, in accordance with an embodiment of the disclosure.

FIG. 9 is a cross-sectional, schematic view depicting a multi-wafer metal organic chemical vapor deposition system including a movable cover plate, in accordance with an embodiment of the disclosure.

FIG. 10A is a top plan view depicting apertures defined within a cover plate, in accordance with an embodiment of the disclosure.

FIG. 10B is a cross-sectional view depicting slits defined within a cover plate, in accordance with an embodiment of the disclosure.

FIG. 11 is a partial, cross-sectional view depicting a substrate wafer residing within a pocket defined in an individual wafer supporting disc of a wafer carrier, in accordance with an embodiment of the disclosure.

FIG. 12 is a top plan view of a separated wafer carrier.

FIG. 13 is a cross-sectional view showing one section of the separated wafer carrier in a raised position.

FIG. 14 is a cross-sectional view of a rotatable platform and satellite ring that is driven by a common motor through separate gears to achieve a differential in rotational speed between rotatable platform and satellite ring.

FIG. 15 is an enlarged cross-sectional view of the satellite of FIG. 14 that consists of a disc with a hub at the bottom.

While embodiments of the disclosure are amenable to various modifications and alternative forms, specifics thereof shown by way of example in the drawings will be described in detail. It should be understood, however, that the intention is not to limit the disclosure to the particular embodiments described. On the contrary, the intention is to cover all modifications, equivalents, and alternatives falling within the spirit and scope of the subject matter as defined by the claims.

### DETAILED DESCRIPTION OF CERTAIN EMBODIMENTS

As wafer sizes for III-V epitaxial growth have increased from 150 mm diameter wafers to larger diameter wafers, such as 200 mm and 300 mm diameter wafers, consumer preference has generally tended towards single wafer reactors, such as the PROPEL™ GaN MOCVD system, due to its superior uniformity and process control. An example embodiment of the PROPEL™ GaN MOCVD system is disclosed in US Pat. App. Publ. No. 2017/0067163, the contents of which are incorporated by reference herein. Advantages for single wafer reactors include rotational averaging for improved deposition uniformity without leading and/or trailing edge effects, low centripetal forces on the wafer, and a wide process window (e.g., 25 Torr, 1450° C., 3000 RPM, etc.). Single wafer reactors are also more readily adaptable to hot wire chemical vapor deposition (alternatively referred to as “catalytic chemical vapor deposition”), a deposition method in which the precursor gas is catalytically disassociated at resistive heating filaments.

However, single wafer reactors are generally considered less cost-effective than multi-wafer batch reactors especially for 150 mm and 200 mm wafers in certain applications. Batch reactors, such as the TurboDisc EPIK® family of MOCVD systems typically have a higher footprint efficiency, higher capital expenditure efficiency, and overall lower cost of ownership. Examples of the TurboDisc EPIK® family of MOCVD systems are disclosed in US Pat. App. Publ. Nos. 2007/0186853 and 2012/0040097, and U.S. Pat. Nos. 6,492,625; 6,506,252; 6,902,623; 8,021,487; and 8,092,599, the contents of which are incorporated by reference herein. With 300 mm diameter wafers, the differential in the metrics between single wafer reactors and batch reactors is relatively small, with single wafer reactors being the preferred choice. However, with wafers having a diameter of less than 300 mm (e.g., 200 mm and 150 mm diameter wafers), higher capacity batch reactors are the preferred choice. Unfortunately, to date, batch reactors have not been able to meet the precision deposition requirements of every application.

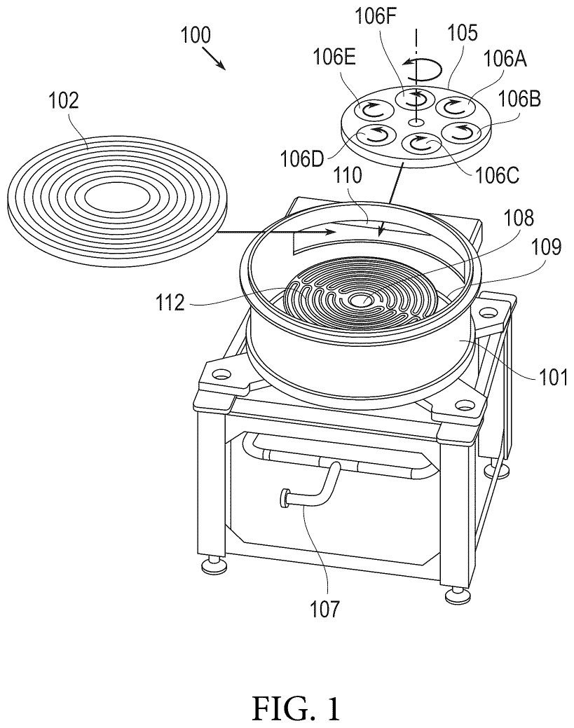

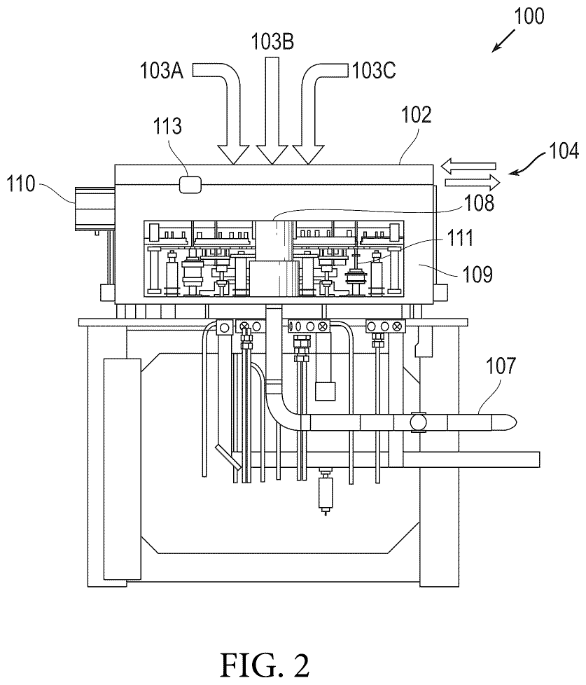

Referring to FIGS. 1-2, a precision, multi-wafer metal organic chemical vapor deposition system 100 configured to achieve the performance of a single wafer reactor, with the productivity and efficiency of a multi-disc batch reactor, is depicted in accordance with an embodiment of the disclosure. In embodiments, the precision, multi-wafer metal organic chemical vapor deposition system 100 can include a reaction chamber 101 (occasionally referred to herein as a “process chamber” or “reactor”), configured to define a process environment space, in which an injector 102 (alternatively referred to herein as a “gas distribution device”) can be arranged within the environment space.

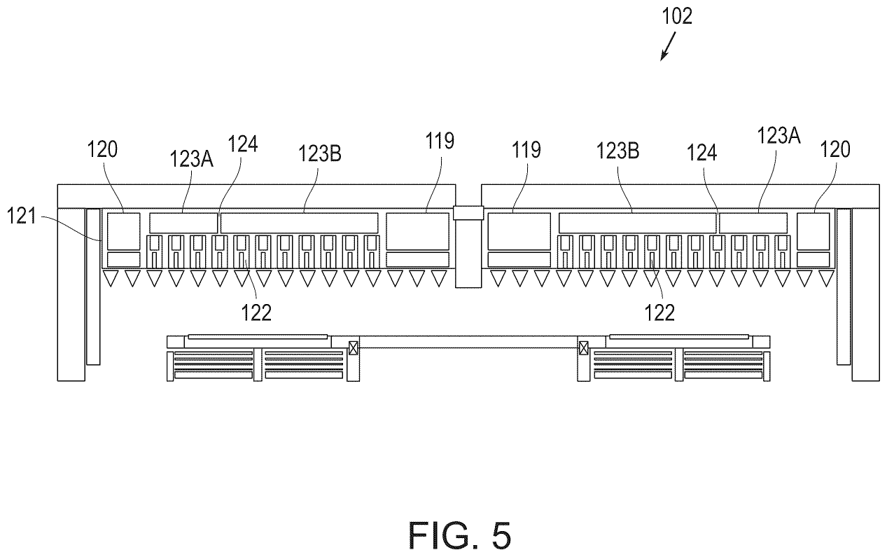

The injector 102 can be connected to a gas delivery system 103A-C (as depicted in FIG. 2) for supplying process gases to be used in the chemical vapor deposition process, such as a carrier gas and one or more reactant gases such as a metal organic compound and a group V source of reactants. Thereafter, the injector 102 can be configured to direct a flow of combined process gases into the process environment. The injector 102 can also be connected to a coolant system 104 (as depicted in FIG. 2) configured to circulate a liquid through the injector 102, to maintain the temperature of the process gas at a desired temperature during operation. One exemplary injector is shown in FIG. 5 and it will be appreciated that the gas delivery system 103A-C delivers the different gases to the gas injector shown in FIG. 5.

The end of the reaction chamber 101 in which the injector 102 of FIGS. 1 and 2 is placed can be referred to as the “top” end of the reaction chamber 101. This end of the chamber typically, but not necessarily, is disposed at the top of the chamber in the normal gravitational frame of reference. Thus, the downward direction as used herein refers to the direction away from the injector 102; whereas the upward direction refers to the direction within the chamber, toward the injector 102, regardless of whether the directions are aligned with the gravitational upward and downward directions. Similarly, the “top” and “bottom” surfaces of elements may be described herein with reference to the frame of reference of the reaction chamber 101 and the injector 102. The construction of an inverted system 100, in which the process gases flow upwardly from a bottom of the reaction chamber 101 is also contemplated.

Following introduction of the process gases into the reaction chamber 101, the process gas flows downwardly toward or across a wafer carrier 105, and over the top surface of the wafer carrier 105, including individual wafer supporting discs or satellites 106A-F, where individual wafer substrates are held. Often the process gas in proximity to the top surface of the wafer carrier 105 is predominantly composed of a carrier gas, such as H₂ and/or N₂, with some amount of first or second reactive gas components. The first reactive gas component can be an alkyl source Group III metal, and the second reactive gas component can be a hydride source Group V element.

The flow of process gas continues to flow around a periphery of the wafer carrier 105 and is eventually exhausted from the reaction chamber 101 through the exhaust system 107, via one or more ports 108, 109 located within the process environment space.

To achieve both the precision of the single wafer reactor and efficiency of a multi-wafer batch reactor, in some embodiments, the wafer carrier 105 can include a plurality of individual satellites 106A-F configured to receive a corresponding plurality of wafer substrates. Although a wafer carrier 105 configured to receive a total of six wafer substrates is depicted, wafer carriers 105 configured to receive a greater or lesser number of wafer substrates are also contemplated.

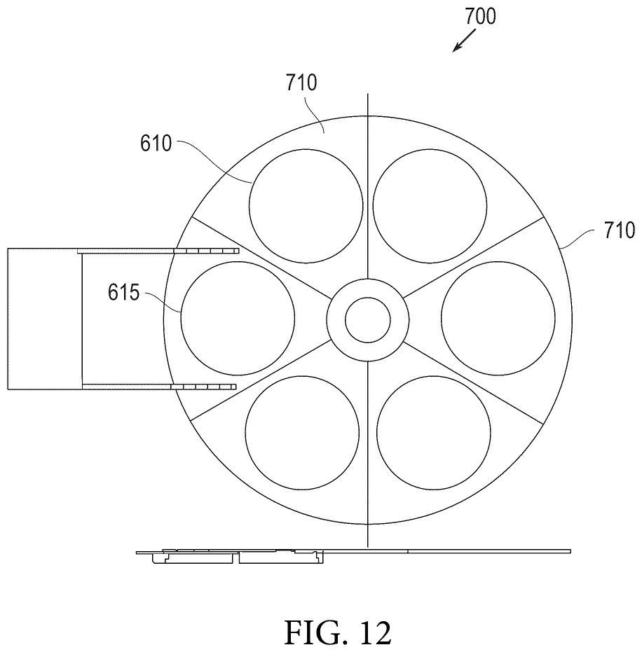

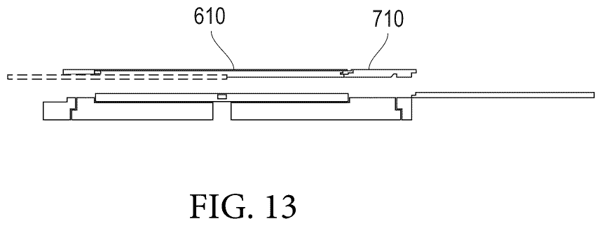

As described herein, the wafer carrier 105 can be in the form of a monolithic carrier with openings to accommodate the satellites or it can be in the form of a segmented carrier (FIGS. 12 and 13). In both applications, a robotic device, such as an end effector, is used to remove the wafer carrier for cleaning, replacement, etc.

To facilitate insertion of new wafer substrates into the chamber 101 and removal of completed wafer substrates from the chamber 101 upon completion of chemical vapor deposition, in some embodiments, the chamber 101 can define an opening 110 through which the planetary wafer carrier 105 can pass to be selectively positioned on a planetary wafer carrier drive mechanism 111 configured to rotate at least one of the individual satellites 106A-F and wafer carrier 105 itself. In embodiments, the drive mechanism 111 can be driven by a variety of motive forces (e.g., gear based, gas driven, etc.). To facilitate ease in installation and removal of the wafer carrier 105 from the chamber 101, the drive mechanism 111 can be configured to releasably engage with the wafer carrier 105. The wafer carrier may be segmented for example into pie shaped segments, so that each segment can be individually loaded or unloaded. Segmenting the carrier reduces the payload on the end-effector and also reduces the footprint of the loading/unloading system connected to the reactor.

In the case that a gas drive mechanism is used, the system utilizes a gas driven rotation drive mechanism to control the rotation of each satellite and the wafer carrier.

One other difference between the system 1000 and the system 200 is that the gas drive mechanism is different. In particular, instead of having a gas drive mechanism that is located below the satellites, the gas drive mechanism can be incorporated into the center region of the system 1000 and more particularly, the gas drive mechanism can be located along the center axis of the reaction chamber 1001. It will thus be appreciated that, in this embodiment, the gas drive mechanism is located below and/or as part of the center gas injector 1010.

A heating assembly 112 can be mounted within the reaction chamber 101 below the wafer carrier 105, such that the heating assembly 120 is configured to distribute heat energy to the wafer carrier 105 to maintain the wafer substrates at a desirable reaction temperature. In some embodiments, in-situ metrology 113 (e.g., a temperature monitor, etc.) (FIG. 2) is provided to monitor at least one of the temperatures of the environment space within the reaction chamber 101 such as the carrier or satellite surface or the surfaces of the wafer substrates themselves.

Accordingly, embodiments of the present disclosure present a chemical vapor deposition system 100 architecture comprising multiple high-speed rotating satellites 106A-F. Each satellite 106A-F emulating a single wafer reactor that is integrated into a batch reactor chamber 101, so that the gas delivery system 103A-C (FIG. 2), injector 102, heater assembly 112, in-situ metrology 113, chamber body 102, exhaust system 107, and carrier drive mechanism 111 are shared between the satellites 106A-F. Sharing such system components significantly improves capital expenditure efficiency and foot-print efficiency with a concomitant reduction in the cost of ownership.

To achieve both the precision of the single wafer reactor and efficiency of a multi-wafer reactor, the individual satellites 106A-F can be configured to follow a circular path within the chamber 101, so that all the satellites 106A-F experience a nearly identical time-averaged process environment for consistency in growth results. For example, in some embodiments, the planetary wafer carrier 105 can be configured to rotate the satellites 106A-F at high speed in counter-rotating pairs (e.g., satellites 106A, 106C & 106E rotate in a clockwise direction, while satellites 106B, 106D & 106F rotate in a counterclockwise direction), while the planetary wafer carrier 105 itself rotates at a substantially lower speed. In the figures, arrows show the direction of rotation. In addition, it will be understood that all satellites can rotate in the in the same direction which can be the same or opposite the direction of rotation of the carrier.

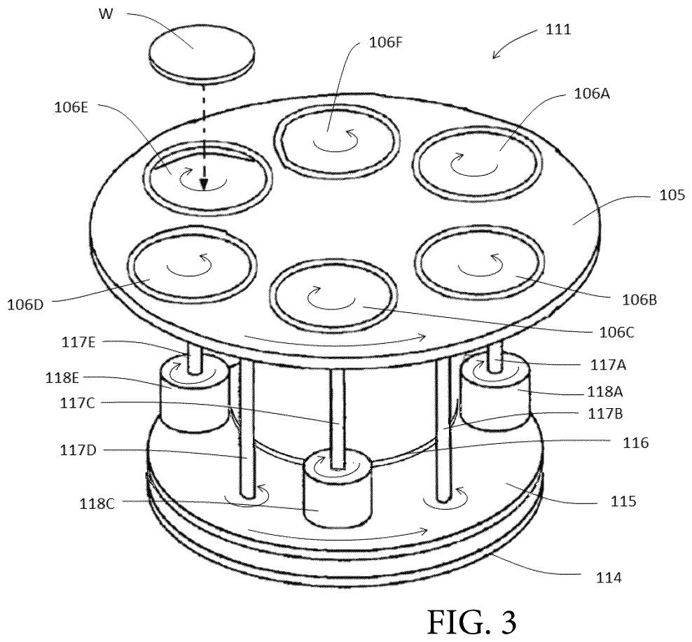

Referring to FIG. 3, a planetary wafer carrier drive mechanism 111 configured to rotate the individual satellites 106A-F in counter-rotating pairs, while at the same time rotating the wafer carrier 105 in either of the clockwise or counterclockwise direction, is depicted in accordance with an embodiment of the disclosure. In embodiments, the drive mechanism 111 can include a base 114 configured to be operably mounted within the reaction chamber 101. The base 114 can be configured to provide a stable platform, fixed in position relative to the reaction chamber 101, onto which rotating components of the drive mechanism 111 can be operably coupled. The rotation direction of either the satellites 106A-F or carrier 105 can be switched periodically so that the time-averaged net rotating speed of all the satellites 106A-F is the same.

Thus, the satellites can rotate in the same direction or in a counter direction to the direction of rotation of the carrier itself.

In some embodiments, the drive mechanism 111 can include a rotatable platform 115 rotatably coupled to the base 114. For example, in some embodiments, the rotatable platform 115 can define a circular channel or groove shaped and sized to overlap with a ledge portion defined by the base 114, with a bearing assembly positioned between the rotatable platform 115 and the base 114 thereby rotatably coupling the rotatable platform 115 to the base 114. Other methods are also contemplated. In some embodiments, the rotatable platform 115 can define a plurality of gear teeth configured to mesh with a pinion or other gear forcibly driven by a motor. Accordingly, activation of the motor can cause the rotatable platform 115 to rotate relative to the base 114 at a desired speed. For example, in some embodiments, the rotatable platform 115 can be configured to rotate at a speed of between about 10 RPM and about 30 RPM relative to the stationary base 114. Other mechanisms of coupling the rotatable platform 115 to the base 114, and to rotatably drive the rotatable platform 115 at various rotational speeds relative to the base 114 are also contemplated.

In some embodiments, the rotatable platform 115 can include a plurality of wafer carrier supports configured to releasably engage with the wafer carrier 105. For example, in one embodiment, the wafer carrier supports can define a generally frustoconical rods tapering toward a top end representing wafer carrier supports, terminating at a flat top surface, thereby enabling the wafer carrier 105 to be lifted free of the rotatable platform 115. Satellites 106A-F can be positioned within stepped recesses defined around the periphery of the carrier 105. In this manner, the satellites 106A-F are retained within the carrier 105 when the carrier is transferred into and out of the chamber 101. In embodiments, there can be a small clearance around the periphery of the satellites 106A-F and the corresponding opening in the carrier 105 so that the periphery of the satellites 106A-F does not contact the inner surface of the opening in the carrier 105 when the satellites 106A-F are rotated at high speed. The satellites 106A-F may also have features that allow them to be centered within the opening in carrier 105, so that the satellites are centered when the carrier 105 is placed on the wafer carrier supports.

In some embodiments, the drive mechanism 111 can further include a satellite ring 116 rotatably coupled to the rotatable platform 115. The satellite ring 116 can define a plurality of gear teeth configured to mesh with a pinion or other gear, which can be forcibly driven by a motor. The motor can be mounted external to the chamber and is coupled to a pinion by a rotating shaft in a vacuum feed-through such as a ferrofluidic feed-through. Accordingly, activation of the motor can cause the satellite ring 116 to rotate relative to both the base 114 and the rotatable platform 115 at a desired speed.

With continued reference to FIG. 3, in some embodiments, a plurality of individual satellite supports 117A-F configured to releasably engage with individual satellites 106A-F of the wafer carrier 105 (as depicted in FIG. 1) can be operably coupled to the rotatable platform 115. In some embodiments, the individual satellite supports 117A-F can be configured to rotate relative to the rotatable platform 115, to impart a rotational force to the individual satellites 106A-F. For example, in some embodiments, the individual satellite supports 117A-F can each be rotatably mounted to the rotatable platform 115 via embedded cylindrical bushings or bearings, with each individual satellite support 117A-F including a gear configured to mate with gear teeth defined along an outwardly facing edge of the satellite ring 116, such that rotation of the satellite ring 116 relative to the rotatable platform 115 causes rotation of the individual satellite supports 117A-F.

Further, in some embodiments, adjacent individual satellite supports 117A-F can rotate in opposite directions from one another with the addition of reversal gears 118A, 118C & 118E associated with every other individual satellite support 117A-F. For example, in one embodiment, a reversal gears 118A, 118C & 118E can be operably coupled to the rotatable platform 115 and associated with individual satellite supports 117A, 117C & 117E, wherein the reversal gears 118A, 118C & 118E are positioned between the gear teeth of the satellite ring 116 and the gears of the individual satellite supports, thereby causing a respective reversal in the rotational direction of individual satellite supports 117A, 117C & 117E relative to the rotational direction of individual satellite supports 117B, 117D & 117F. In some embodiments, the respective gears of the individual satellite supports 117A-F can be at least partially enclosed within a cover to shield the gears from the process environment, thereby inhibiting accumulation of deposition material on the surface of the gears and other moving components.

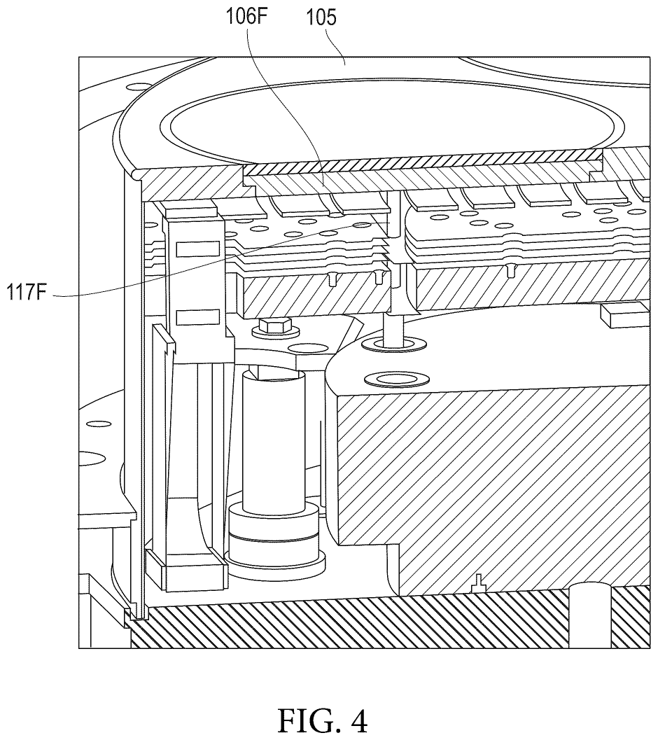

The use of other mechanisms to affect a rotation of the individual satellite supports 117A-F is also contemplated, including use of a flow of gas directed at one or more vanes extending from a bottom surface of the individual satellite supports 117A-F or below the surface of satellites 106A-F is also contemplated. With additional reference to FIG. 4, in some embodiments, the individual satellite supports 117A-F can be configured to impart rotational forces on the individual satellites 106A-F of the wafer carrier 105, wherein adjacent satellites 106A-F rotate in opposite directions at a desired rotation speed. By counter-rotating adjacent satellites 106A-F, process gas flow interaction and instability due to high velocity gas flow exiting the periphery of each disk 106A-F is reduced. For example, in some embodiments, individual satellite supports 117A-F can be configured to rotate at a speed of between about 600 RPM and about 1200 RPM; although other rotational speeds (including higher rotational speeds of up to 3000 RPM) are also contemplated. In various embodiments, the ratio of the rotational speed of the rotatable platform 115 to the rotational speed of the disks (e.g., disks 106A-F) can be between about 1:20 and about 1:200, such that the satellites 106A-F rotate in a range from between about 20 times to about 200 times the rotational speed of the rotatable platform 115. In some embodiments, the ratio of speeds for the satellite to the carrier can be 0.5:1 to 2:1.

In some embodiments, the satellite supports 117A-F may be slightly individually adjustable so that they can be moved up and down to raise or lower satellites 106A-F. In embodiments, these adjustments can be made either when the reactor is set up or may be electrically actuated through recipe control (e.g., via a piezoelectric drive mechanism), as fine adjustment of the gap between heater assembly 112 and satellites 106A-F can provide for fine tuning of wafer temperature so that all wafers are at the same temperature.

With continued reference to FIG. 1, another feature enabling the system 100 to achieve the performance of a single wafer reactor with the efficiency of a multi-disc, batch reactor includes the use of a multi-zone injector 102. For example, with additional reference to FIG. 5, in some embodiments the overhead injector 102 (above the wafers) can include at least two distinct zones, including a generally centrally located inner purge 119 at least partially surrounded by an outer purge 120 arranged in proximity to a periphery 121 of the multi-zone injector 102. In some embodiments, a combined hydride zone 122 and a first and second alkyl zone 123A, 123B can be positioned between the inner or central purge 119 and the outer purge 120.

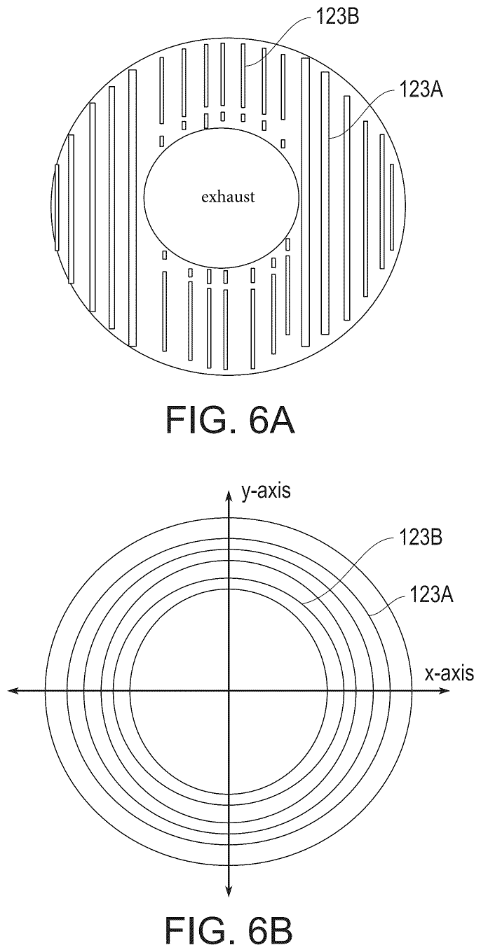

With additional reference to FIGS. 6A & 6B, in some embodiments, the multi-zone injector 102 can use an array of linear or circular/arc shaped injectors for the dispensation of reactant and non-reactant gases into the deposition system 100. In some embodiments, first and second alkyl zones 123A, 123B can be separated by a partition, with the first alkyl zone 123A overlapping a periphery of the wafer carrier 105 while the second alkyl zone 123B overlaps a remainder of the wafer carrier 105. Accordingly, the reactant gases can be introduced into the reactor chamber 101 via an array of linear or circular/arcuate ports. In some embodiments, the arcuate ports can be oval (e.g., having slightly different diameters along the x- and y-axes as an intermediate between linear and circular ports.

The center exhaust is shown in FIG. 6A.

In some embodiments, the reactant gas emitted from the first alkyl zone 123A can include a higher concentration of Group III alkyl metals, relative to the reactant gas emitted from the second alkyl zone 123B. The increased concentration of Group III alkyl metals in the first alkyl zone 123A can serve to improve growth uniformity and promote a more efficient use of the reactant chemicals during the CVD process, thereby reducing production costs and improving quality of the resultant products.

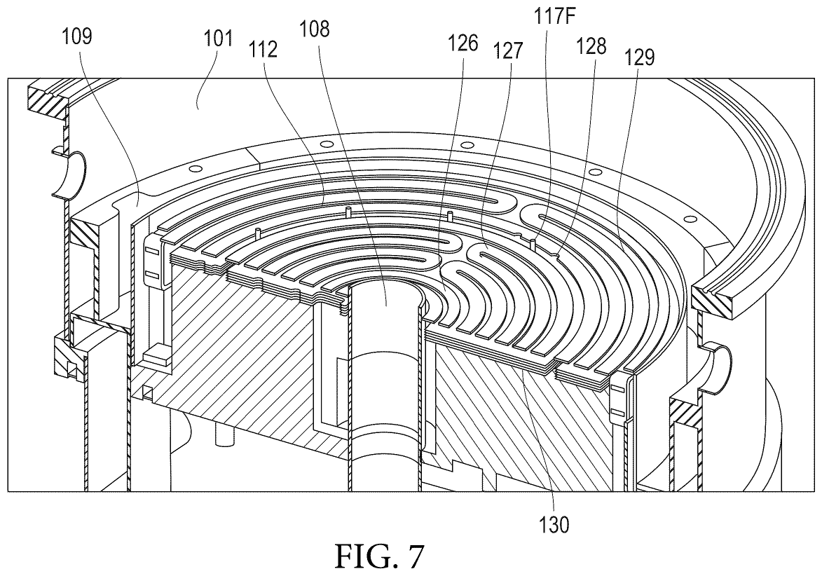

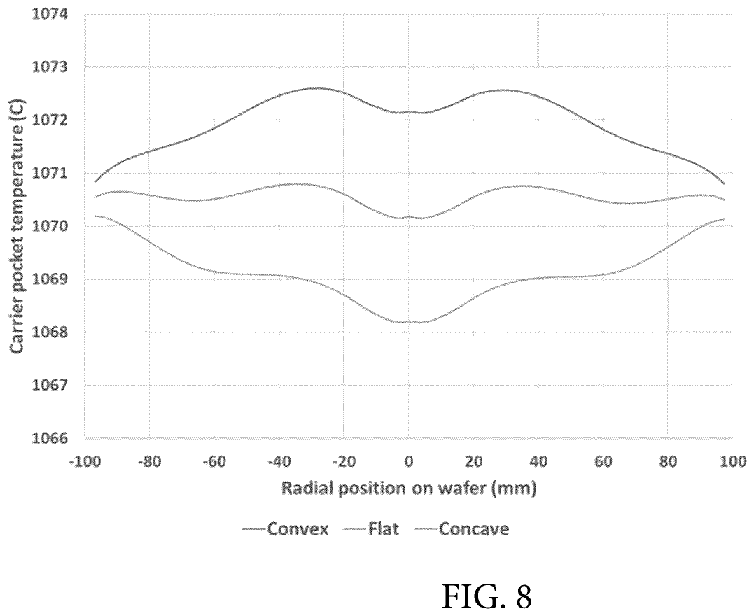

Yet other features enabling the system 100 to achieve the benefits of both a single wafer reactor with the efficiency of a multi-disc reactor include the employment of both a central exhaust port 108 and a peripheral exhaust port 109 as an aid in reducing an undesirable accumulation of deposition material on the walls of the reactor 101, as well as a multi-zoned heater assembly 112 configured to promote a more even distribution of heat to the rotating wafer substrates. For example, with additional reference to FIG. 7, heater assembly 112 including an individually controllable first zone 126, second zone 127, third zone 128, and fourth zone 129 is depicted in accordance with an embodiment of the disclosure. In such embodiments, the heater assembly 112 can be configured to control a radial temperature profile of the wafer carrier 105; thereby enabling radial temperature distributions (e.g., concave/convex temperature distributions) among the rotating individual satellites 106A-F, as well as the wafer substrates supported thereon, such as that depicted in FIG. 8.

As depicted in FIG. 7, in some embodiments, the individual satellite supports 117A-E can be configured to extend upwardly through the heater assembly 112 between the second zone 127 and the third zone 128, such that portions of the individual satellites 106A-F further radially outward from the individual satellite supports 117A-E are proportionally exposed to more heat emanating from the third zone 128 than the second zone 127. One or more heat shields 130 positioned beneath the heater assembly 112 can be configured to minimize heat transfer to the planetary wafer carrier drive mechanism 111. A water-cooled plate that holds the heater assembly above the planetary wafer carrier drive mechanism 111 further reduces heat transfer.

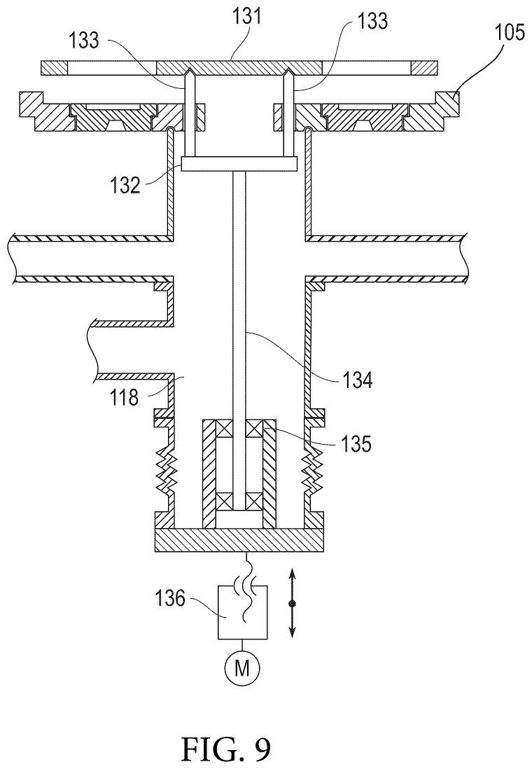

In some embodiments, the system 100 can include movable cover plate configured to serve as a barrier to deposition gases during operation for the purpose of minimizing growth rate non-uniformity induced around an edge of the wafers. For example, with reference to FIG. 9, a system 100 including a movable cover plate 131 is depicted in accordance with an embodiment of the disclosure. As depicted, the system 100 can include a lift mechanism 132 for transitioning (e.g., raising and lowering) the cover plate 131 between an initial home position (e.g., used during loading and unloading of the wafer carrier 105 into and out of the reaction chamber 101) and an active deposition position (as depicted in FIG. 9) (e.g., used during the chemical vapor deposition process). In the home position, cover plate 131 rests on wafer carrier 105.

In some embodiments, the lift mechanism 132 configured to transition the cover plate 131 between the home position and the active position can include a plurality of pins 133 configured to lift and support the cover plate 131. The plurality of pins 133 can pass through apertures defined in the wafer carrier 105 and can be supported by a rotating shaft 134 and one or more bearing assemblies 135. A motor/actuator 136 can be configured to raise and lower the rotating shaft 134 between the home position and the active position. In some embodiments, the motor 136 can be configured to rotate the cover plate 131 relative to the reaction chamber. In other embodiments, the cover plate 131 can be rotatably driven by a rotation of the wafer carrier 105, as rotation of the wafer carrier 105 exerts rotational force upon the plurality of pins 133 passing through the wafer carrier 105, such that the lift mechanism 132 freely rotates about its axis synchronously with the wafer carrier 105.

Lift mechanism 132 can have a capability to rotatably index to a desired home position when it is retracted from the carrier so that pins 133 are concentric with holes in carrier 105 when the carrier is in the home position. This may be achieved by a cam that is fixed to lift mechanism 132 that engages with rollers affixed to the inside of the exhaust tube when lift mechanism 132 is fully retracted. Further a non-contact rotary encoder (such as a magnetic encoder) can be attached to the base of lift mechanism 132 to provide the rotational position of lift mechanism 132 so that the carrier 105 can be rotated to the correct angular position to engage with lift mechanism 132 when lift mechanism 132 is raised to engage the carrier 105 and cover 131.

In some embodiments, the lift mechanism 132 can be at least partially positioned within the central exhaust tube 108. Lift mechanism 132 may include a rotational alignment mechanism such as a cam/guide so that the lift mechanism returns to its correct angular orientation when lowered and disengaged from the carrier even when the carrier is not rotationally aligned to its home position. This ensures that when the carrier is loaded into the reactor in its correct rotational orientation, lift mechanism is rotationally aligned with the carrier.

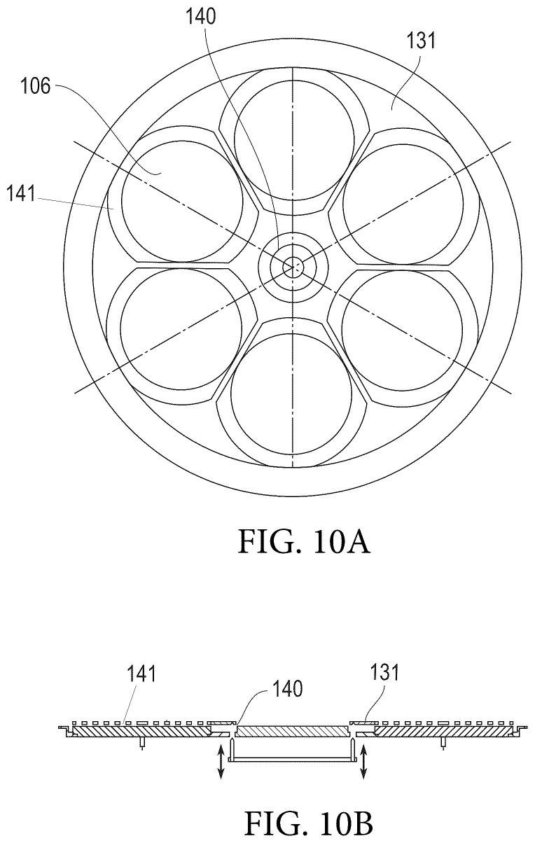

With reference to FIGS. 10A and 10B, in some embodiments, the cover plate 131 can define a central opening 140 concentric with a central exhaust 108, with a plurality of openings (apertures) 141 defined over each of the wafer supporting discs (satellites) 106 that are associated with the underlying carrier. In embodiments, the boundaries of the opening (aperture) 141 can be the same, slightly larger, or slightly smaller than the diameter of the wafer positionable on the wafer supporting discs 106 which lies below the cover plate 131 as shown in the figures. The overall shape of the opening 141 can be circular, oval, or an arbitrary shape configured to optimize deposition uniformity.

As depicted, each of the openings 141 can comprise a single large aperture, an array of holes, or an array of linear or concentric slits (such as that depicted in FIG. 10B). In embodiments, the openings 141 may have a circular or hexagonal cross section and may be arranged in a square, circular or hexagonal pattern. The axis of the openings 141 may be perpendicular or tilted relative to the surface of the cover plate 131. For linear or concentric slits, the sidewalls of the slits (or slats) may either be perpendicular to a major surface of the cover plate 131 or slanted (like louvers) relative to the major surface of the cover plate 131. The slanted design of slits or tilted orientation of the holes can enable gas to flow from the injector 102 to the surface of the wafers, while at least partially blocking radiative heat loss from the wafers to the injector 102. Accordingly, in applications, where the precursor gases reach the wafer surfaces without pre-reaction, a single large opening aperture may be the preferred implementation. Conversely, in other applications, such as CVD SiC, where the precursor gases are pre-heated and partially reacted, heat loss from the wafers may be minimized through the implementation of slanted slits or tilted holes.

In some embodiments, the cover plate 131 may be fabricated of a transparent material, such as a transparent, inert material at high temperatures (e.g., quartz or sapphire). In such an embodiment, the transparent cover plate 131 can generally operate cooler than a cover plate constructed of an opaque material, which may serve to reduce deposition the cover plate 131. Constructing the cover plate 131 of a transparent material also provides optical access for measurement of the wafer carrier 105 temperature using externally mounted pyrometers. In embodiments, openings 141 in the cover plate 131 can provide optical access for measurement of the wafer supporting discs 106 and wafer temperatures using in situ metrology (e.g., one or more externally mounted pyrometers).

For applications such as CVD SiC, or in cases where the heat loss from the wafer and wafer carrier 105 is to be minimized, the cover plate 131 can be constructed of an opaque, inert material and high temperatures (e.g., SiC coated graphite or CVD SiC), so that the cover plate 131 can be heated by the wafer carrier 105 to at least partially serve as a as a heat shield. In such applications, openings in the cover plate 131 to provide optical access to the wafer carrier 105 surface may be desired for pyrometer-based measurement of the wafer carrier 105 temperature. In embodiments, these openings may be filled by an inert, transparent material (e.g., quartz or sapphire).

In embodiments, the cover plate 131 can be smooth and rounded, such that film deposited on the cover plate 131 adheres well to its surface, similar to films deposited on the wafer surface. Thereafter, after each deposition run, the cover plate 131 can be removed from the reactor 102, along with the wafer carrier 105 and wafer supporting satellites 106 and cleaned ex-situ before re-use. In some embodiments, cleaning may be desired to prevent memory effects or particulate shedding from the coated surfaces of the cover plate 131, carrier 105 and wafer supporting satellites 106.

The cover plate 131 can be configured to slow down high velocity gas exiting from the periphery of the fast-rotating satellites, thereby channeling the gas towards the inner and outer exhausts 108, 109. In the absence of a cover plate 131, high velocity gas exiting the periphery of the satellites can swirl upwards towards the injector. This swirling action (sometimes referred to as “recirculation”) can induce unwanted gas phase reactions, and in an extreme case result in parasitic deposition on the injector. Any parasitic deposition on the injector is undesirable, as it causes memory effects and can become a source of particles that can become embedded in films deposited on the wafers.

The desired vertical gap or spacing between the surface of the wafer carrier 105 and the lower surface of the cover plate 131 may be process dependent. For example, the cover plate 131 may be located close to an edge of a boundary layer over the satellites, such that most of the gas exiting the satellites is channeled under the cover plate 131 towards the inner and outer exhausts 108, 109. Since the thickness of the boundary layer may be dependent on the process conditions (e.g., the rotational speed, pressure, and gas composition), the vertical gap may be adjustable for each process condition. The cover plate 131 must also rotate synchronously with the wafer carrier 105 so that openings 141 of the cover plate 131 remains over corresponding wafers. Such functionality can be achieved using a lift mechanism 132 that is actuated externally to raise the cover plate 131 from the wafer carrier 105 surface to a desired height.

At high operating pressures, a smaller distance between the cover plate 131 and a top surface of the wafer may be desirable to inhibit buoyancy induced recirculation between the wafer carrier 105 and the cover plate 131, while at lower operating pressures, a larger gap may be desired to slow down the depletion of the reactants without the need to use high gas flow rates. Thus, the zoning of the central injector and the gap between the wafer carrier 105 and the cover plate 131 may be recipe selectable. In embodiments, the cover plate can be configured to shield the wafers from particulates during carrier transfer and those originating from the chamber walls.

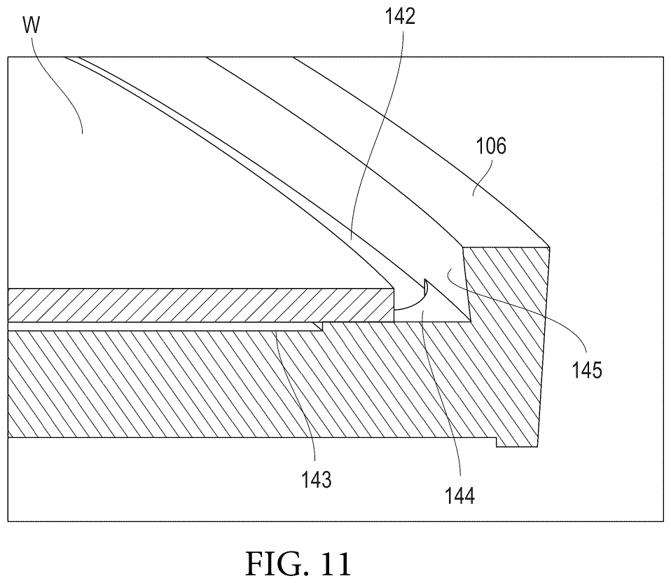

With additional reference to FIG. 11, in operation, a disk-like wafer (W) formed from sapphire, silicon carbide, or other crystalline substrate, can be disposed within pockets 142 of each satellite 106. Typically, the wafer has a thickness which is small in comparison to the dimensions of its major surfaces (e.g., top and bottom surfaces). For example, a circular wafer of about 2 inches (50 mm) in diameter may be about 430 μm thick or less. The wafer can be disposed with its top surface facing upwardly, so that the top surface is exposed at the top of the wafer carrier 105, and its bottom surface rests on a pocket floor 143 of the wafer pocket 142.

In a typical chemical vapor deposition process, the wafers are loaded into the chamber 101, such that the top surfaces of the wafers are exposed to flow of gas from the injector 102. The heating assembly 112 can be activated, and the wafer carrier drive mechanism 111 can operate to rotate the wafer carrier 105 and respective individual satellites 106 relative to the reactor chamber 101. The gas delivery system 103A-C is configured to supply gases through the injector 102. The gases pass downwardly toward or crosswise across the wafer carrier 105, over the top surface of the wafer carrier 105 and the top surfaces of the wafers, and downwardly around the periphery and center of the wafer carrier 105 to the exhaust ports 108, 109. Thus, the top surface of the wafer carrier 105 and the top surfaces of the wafers are exposed to a process gas including a mixture of the various gases supplied by the gas delivery system 103A-C. When a cover plate 131 is present, a portion of the process gases flow under the cover plate 131 for exhaustion through the exhaust ports 108, 109.

The heater assembly 112 can be configured to transfer heat to the bottom surface of the wafer carrier 105, principally by radiant heat transfer. The heat applied to the bottom surface of the wafer carrier 105 flows upwardly through the wafer carrier 105 to the top surface of the wafer carrier, as well as through the top surfaces of the wafers. As depicted in FIG. 2, the system 100 can include features designed to determine uniformity of heating of the top surface of each wafer. For example, in one embodiment, in situ metrology 113 can be configured to receive temperature information that can include temperature measurements. For example, in one embodiment, the in-situ metrology 113 can be a non-contact instrument for measuring temperature, such as an optical pyrometer or infrared temperature sensor. In addition, the in-situ metrology 113 can receive wafer carrier positional information, which in one embodiment can be derived from the wafer carrier drive mechanism 111. With this information, in situ metrology 113 can construct a temperature profile of the wafers on wafer carrier 105. The temperature profile can represent a thermal distribution on the surface of each of the wafers. For example, if in-situ metrology 113 is aimed at a location on the satellites that lies on the path that is traced by the center of satellites 106A-F, a temperature map of each wafer (as depicted in FIG. 8) can be created based on a known rotation of the satellites 106A-F and carrier 105. Additional in-situ metrology 113 directed towards various locations on the carrier 105 can be used to measure the temperature of carrier 105.

With continued reference to FIG. 11, wafer satellites 106 can be formed of numerous types of materials, such as graphite, SiC, metal, or ceramic. In some embodiments, it is desirable to form the satellite 106 of a material that can easily accept additional materials 144 in localized areas of different materials or the same material with a different orientation or with modified properties in localized areas. For example, as depicted in FIG. 13, additional materials 144 added to the pocket floor 143 and/or peripheral wall surface 145 of the wafer pocket 142 can be configured to provide additional support for wafer (W) and/or compensate for thermal non-uniformities. In one embodiment, additional materials 144 can be added to or removed from the pocket floor 143 and/or the wall surface 145 by a contouring apparatus.

Additional materials 144 can be positioned at several locations along the peripheral wall or bottom surface of the wafer. Additional materials 144 can be rectangular, stepped, triangular, or sloped in shape. Material 144 can be added, for example, by evaporation, sputtering, plating, CVD, or positioning an additional support therein. Portions of the satellites 106 can be masked so that the additional material 144 is deposited in only certain areas of the satellites 106. As depicted in FIG. 11, the wafer pockets 142 and additional materials 144 can define various gaps or step heights spanning from the pocket floor 143 to the bottom surface of the wafer. In some embodiments, changes in the step height can affect the thermal conductivity of the wafer carrier, to promote a more uniform temperature profile across the top surface of the wafer. In one embodiment, the satellite 106 can include a heat spreader plate configured to provide a controlled gap between the pocket floor 143 in the bottom surface of the wafer, when the wafer is placed within a cavity defined by the heat spreader plate. In embodiments, the heat spreader plate can be constructed of a material with high thermal conductivity, such as CVD SiC or pyrolytic graphite.

In one embodiment, portions of the pocket floor 143 are contoured away to adjust the various step heights spanning from the pocket floor 143 to the bottom surface of the wafer. For example, in one embodiment, a wafer supporting disc 106 is initially produced with a pocket floor 143 having an elevation equal to the highest anticipated point within a finalized pocket floor 143, such that only the removal of material needs to be carried out to produce the final pocket floor 143. Material can be removed from the satellite 106, for example, by machining localized areas in the pocket 142. In such an embodiment, it is desirable to form the satellite 106 of a material that can be easily machined in localized areas to conform to a predefined contour. The satellite 106 can be machined with continuous contours or can be machined in localized areas by pecking with a specialized cutting tool. For example, a small diameter diamond cutting tool can be used. Cutting tools that operate at high speeds, such as cutting tools that use air turbine spindles can provide the relatively high accuracy needed for machining small pixels.

Further, in some embodiments, the peripheral exhaust port 109 (e.g., the annular region in proximity to the reactor chamber wall 101) or the central exhaust port 108 can include water-cooled vanes configured to cool exhausted gas in order to suppress gas phase particulate generation or accumulation of debris below the top plane of the wafer carrier 105. Further, the wafer carrier 105 can include surface features along a periphery of the inner exhaust in order to tailor thickness of a reactant gas boundary layer, thereby improving deposition uniformity. The boundary layer thickness can also be adjusted by setting the height of the satellite supports 117 so that the surfaces of the satellites are level with, above or below the top surface of the carrier 105.

As mentioned, the wafer carrier can be in the form of a separated (segmented) carrier construction as shown in FIGS. 12 and 13 as opposed to a monolithic carrier construction. As illustrated, in this embodiment, a carrier 700 is formed of a plurality of discrete sections 710 (“pie shaped sections”) with each section 710 including one satellite 610/satellite ring 615. In this embodiment, the end effector can be in the form of a fork design end effector and the carrier 700 includes complementary grooves that received the forks (arms) of the end effector. FIG. 13 shows the lifting of one discrete section 710 from the main body of the carrier 700 by the fork design end effector. The lifted discrete section 710 includes the one satellite 610/satellite ring 615.

The individual sections 710 are removed with a device, such as a robotic end effector, that is configured to remove the carrier ring and wafer. The carrier 700 can be rotated in an indexed manner to allow for the individual and successive removal of the carrier sections 710 through a load port or the like. Clearance to remove the carrier can be generated by moving down an exhaust ring or by moving a segment of the exhaust ring.

The automated loading/unloading process can include the following steps: moving one carrier section 710 out of the reactor using a robotic device (end effector) and placing the removed section 710 into a wafer loading and unloading station. Once the carrier section is at the wafer loading and unloading station, the wafer 611 is separated (lifted) from the satellite 610/satellite ring 615 and is further processed and/or transported to a different station. After the wafer is removed, the section 710 and the satellite 610/satellite ring 615 are moved to storage.

A cleaned (or new) carrier section 710 (with cleaned satellite 610/satellite ring 615) is then brought into the reaction chamber. For example, the cleaned carrier section 710 (with cleaned satellite 610/satellite ring 615) can be brought to the wafer loading and unloading station. A fresh wafer 611 is loaded onto the section 710 (onto the satellite 610/satellite ring 615) and then the section 710 is then loaded back into an open space in the segmented carrier within the reaction chamber. This process is repeated using an indexed controller that rotates the segmented carrier in indexed increments to the position at which each carrier section 710 is unloaded/loaded. In other words, the carrier is rotated in an indexed manner to position one dirty carrier section 710 at the carrier section load/unload position. Once the dirty carrier section 710 is at this position, it is unloaded and processed as described above and a cleaned carrier section 710 is added back to the carrier. In this way, sequential removal and the replacement of the carrier sections 710 results.

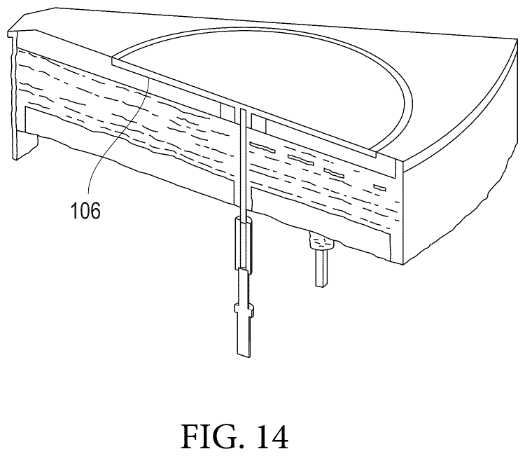

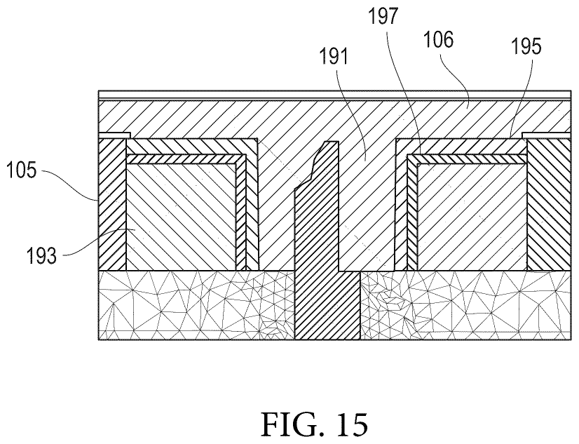

Referring to FIGS. 14 and 15, in some embodiments, a rotatable platform and satellite ring may be driven by a common motor through separate gears to achieve a differential in rotational speed between rotatable platform and satellite ring 116. This results in a differential speed between carrier 105 and satellites 106A-F. This embodiment is preferred when the carrier rotational speed substantially exceeds the satellite rotational speed such as for example when the carrier is rotating at 100-1200 rpm and the satellite is rotating at 20-40 rpm. In this embodiment, substantial centripetal forces act on satellites 106A-F. To counter-act these centripetal forces, satellites 106A-F may be mounted in the carrier via a bushing.

1. In one embodiment, the carrier rotates at >50 rpm and preferably at >100 rpm, while the satellites 106A-F are rotating slowly (<30 rpm) in order to draw the reactants towards the wafer surface and away from the ceiling (to minimize dilution by the ceiling purge). However, as mentioned herein, in other embodiments, the satellites can rotate at higher speeds relative to the carrier. For example, the wafer carrier body can rotate relative to the reaction chamber at a rate between 10 RPM and 30 RPM and each of the plurality of wafer carrier discs (satellites) rotates relative to the reaction chamber at a rate between 600 RPM and 1200 RPM.

Satellite 106 consists of a disc with a hub 191 at the bottom. The hub 191 is positioned within a bushing 193. The bushing 193 is embedded in the base of carrier 105. The interface between the satellite hub 191 and the bushing 193 is designed to have low friction so that the torque required to rotate the satellite under the frictional forces induced by the centripetal forces are minimized. Low friction interfaces can be obtained by coating the mating surfaces with high temperature compatible solid lubricants such as MoS₂ and WS₂. The bushing material and dimensions are chosen to minimize the thermal imprint of the hub 191 on the wafer. The bushing 193 may consist of a combination of materials such as fused silica, graphite, SiC, and molybdenum to achieve the desired properties. For example, as illustrated above, bushing 193 fabricated from quartz may contain two concentric liners 195, 197. The liners 195, 197 can be fabricated from molybdenum and the interfaces between the two liners 195, 197 can be coated with a low friction solid lubricant.

In this configuration, satellite supports 117F contain a flexural element to accommodate a slight radial movement of the satellite due to thermal expansion of the carrier. The interface between the end of satellite supports 117F and the satellites 106A-F is designed to rotatably couple the rotary motion of satellite supports 117F and transmit the torque required to overcome the frictional forces in the bushing.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

What is claimed is:

1. A multi-wafer metal organic chemical vapor deposition system in which adjacent wafers positioned within the system rotate about their own axes, the system comprising:
a reaction chamber having an exhaust system;
a multi-wafer carrier including a wafer carrier body and a plurality of wafer carrier discs supported within the wafer carrier body;
an injection block having at least one injection zone positioned over the multi-wafer carrier;
a center gas flow port positioned in a center of the multi-wafer carrier, wherein the center gas flow port comprises an exhaust port; and
a heater assembly positioned beneath the multi-wafer carrier.

2. The multi-wafer metal organic chemical vapor deposition system of claim 1, further comprising a cover plate configured to be raised relative to a surface of the multi-wafer carrier.

3. The multi-wafer metal organic chemical vapor deposition system of claim 1, wherein the multi-wafer carrier body is configured to rotate.

4. The multi-wafer metal organic chemical vapor deposition system of claim 1, wherein the multi-wafer carrier body rotates at a speed substantially lower than a rotational speed of the plurality of wafer carrier discs.

5. The multi-wafer metal organic chemical vapor deposition system of claim 4, wherein adjacent wafer carrier discs of the plurality of wafer discs rotate in opposite directions.

6. A multi-wafer carrier for a chemical vapor deposition configured to minimize growth rate non-uniformity induced around an edge of substrate wafers positioned within the multi-wafer carrier during a chemical vapor deposition process, the system comprising:
a wafer carrier body;
a plurality of wafer carrier discs supported within the wafer carrier body; and
a cover plate configured to transition relative to an upper surface of the wafer carrier body between a home position and an active position.

7. The multi-wafer carrier of claim 6, wherein the cover plate is transitioned between the home position and the active position by a lift mechanism comprising an actuator.

8. The multi-wafer carrier of claim 7, wherein the wafer carrier body and the cover plate rotate together.

9. The multi-wafer carrier of claim 6, wherein the cover plate defines a plurality of openings corresponding to each of the substrate wafers positioned within the multi-wafer carrier.

10. The multi-wafer carrier of claim 6, wherein the openings at least partially overlap portions of the substrate wafers positioned within the multi-wafer carrier.

11. The multi-wafer carrier of claim 6, wherein the openings are at least one of circular, oval, or non-polygonal shape configured to optimize deposition uniformity.

12. The multi-wafer carrier of claim 6, wherein the cover plate is constructed of at least a semi-transparent material.

13. A precision, multi-wafer metal organic chemical vapor deposition system, the system comprising:
a reaction chamber;
a multi-zone injector;
a multi-wafer carrier having a wafer carrier body and a plurality of wafer carrier discs supported within the wafer carrier body; and
a cover plate configured to be raised and lowered relative to an upper surface of the multi-wafer carrier.

14. The system of claim 13, wherein the cover plate defines a plurality of openings corresponding to the plurality of wafer carrier discs.

15. The system of claim 13, wherein the multi-wafer carrier body rotates at a speed substantially lower than a rotational speed of the plurality of wafer carrier discs and the plurality of wafer carrier discs rotate in counter-rotating pairs in that a first set of wafer carrier discs of the plurality of wafer carrier discs rotate in a clockwise direction, while a second set of wafer carrier discs of the plurality of wafer carrier discs rotate in a counterclockwise direction.

16. The system of claim 15, wherein the first set of wafer carrier discs and the second set of wafer carrier discs are arranged in an alternating manner.

17. The system of claim 13, wherein the multi-zone injector is located above the multi-wafer carrier, the multi-zone injector comprises at least two distinct zones including a centrally located inner purge at least partially surrounded by an outer purge in proximity to a periphery of the multi-zone injector.

18. The system of claim 17, further including a combined hydride zone and first and second alkyl zones that are all positioned between the inner purge and outer purge.

19. The system of claim 17, wherein the multi-zone injector comprises an array of linear or circular/arc shaped injectors that include reactant gas holes for injecting reactant gases into the reactant chamber.

20. The system of claim 19, further including a combined hydride zone and first and second alkyl zones that are all positioned between the inner purge and outer purge, wherein the reactant gas emitted from the first alkyl zone includes a high concentration of Group III alkyl metal relative to reactant gases emitted from the second alkyl zone.

21. The system of claim 20, wherein the first and second alkyl zones are separated by a partition with the first alkyl zone overlapping a periphery of the wafer carrier, while the second alkyl zone overlaps a remainder of the wafer carrier.

22. The system of claim 13, further including a center exhaust port located centrally within the wafer carrier and a peripheral exhaust port.

23. The system of claim 22, wherein the cover plate includes a central opening with the center exhaust port.

24. The system of claim 13, further including a heater assembly located below the multi-wafer carrier, the heater assembly including an individually controllable zones including a first zone, second zone, third zone and fourth zone.

25. The system of claim 24, wherein the first zone, second zone, third zone and fourth zone are concentrically arranged.

26. The system of claim 13, further including a drive mechanism that is operatively coupled to the multi-wafer carrier, the drive mechanism including a base operably and fixedly mounted within the reaction chamber; a rotatable platform rotatably coupled to the base with a bearing assembly positioned between the rotatable platform and the base; wherein rotation of the rotatable platform is translated into rotation of at least one of the wafer carrier body and the plurality of wafer carrier discs.

27. The system of claim 26, further including a satellite ring rotatably coupled to the rotatable platform and driven by a motor and a plurality of satellite supports configured to releasably engage with the plurality of wafer carrier discs, the plurality of satellite supports are rotatably mounted to the rotatable platform so as to impart a rotational force to the plurality of wafer carrier discs.

28. The system of claim 27, further including a plurality of reversal gears associated with every other individual satellite support.

29. The system of claim 13, wherein the wafer carrier body rotates relative to the reaction chamber at a rate between 10 RPM and 30 RPM and each of the plurality of wafer carrier discs rotates relative to the reaction chamber at a rate between 600 RPM and 1200 RPM.

30. The system of claim 13, wherein the multi-zone injector is operatively coupled to a coolant system that is configured to circulate a coolant liquid through the multi-zone injector to maintain a temperature of process gas at a desired temperature during operation.

31. The system of claim 13, wherein the multi-zone injector delivers process gas that includes a carrier gas and one or more reactant gases.

32. The system of claim 31, wherein the one or more reactant gas comprises a metal organic compound and a group V source of reactants.

33. A multi-wafer metal organic chemical vapor deposition system in which adjacent wafers positioned within the system rotate about their own axes, the system comprising:
a reaction chamber having an exhaust system and a ceiling;
a multi-wafer carrier including a wafer carrier body and a plurality of wafer carrier discs supported within the wafer carrier body;
a gas injector for injecting gas into the reaction chamber; and
a movable cover plate that is configured to act as a barrier to deposition gases for minimizing growth rate non-uniformity induced around edges of the wafer, the movable cover plate moving between a lowered home position that allows for loading and unloading of the wafer carrier body and a raised operating position that comprises an active deposition position.

34. The multi-wafer metal organic chemical vapor deposition system of claim 33, further comprising a lift mechanism for moving the cover plate between the lowered home position and the raised operating position and is configured to permit rotation of the multi-wafer carrier.

35. The multi-wafer metal organic chemical vapor deposition system of claim 34, wherein the lift mechanism comprises a plurality of lift pins that pass through corresponding through holes in the multi-wafer carrier and are configured to drive the cover plate from the lowered home position to the raised operating position and permit lowering of the cover plate.

36. The multi-wafer metal organic chemical vapor deposition system of claim 35, wherein the lift mechanism is rotatable.

37. The multi-wafer metal organic chemical vapor deposition system of claim 36, wherein the lift mechanism includes a motor that is configured to controllably rotate the cover plate between a plurality of indexed positions.

38. The multi-wafer metal organic chemical vapor deposition system of claim 34, wherein the lift mechanism is at least partially located in a center exhaust port that is located in a center of the multi-wafer carrier.

39. The multi-wafer metal organic chemical vapor deposition system of claim 37, wherein the gas injector comprises a center gas injector that is movable between a raised operating position and a lowered home position and movement of the center gas injector between the lowered home position and the raised operating position is translated into movement of the cover plate.

40. The multi-wafer metal organic chemical vapor deposition system of claim 37, further including a water-cooled plate disposed above the cover plate for thermal regulation of the cover plate.

41. The multi-wafer metal organic chemical vapor deposition system of claim 37, wherein the cover plate includes a central opening concentric with a center exhaust port of the reaction chamber and a plurality of secondary openings that are for placement over the plurality of wafer carrier discs.
